(19) United States
(12) Patent Application Publication
(10) Pub. No.: US 2010/0102904 A1
(43) Pub. Date: Apr. 29, 2010

(54) FLUXONIC DEVICES

(76) Inventors: Feo V. Kusmartsev, Leicestershire (GB); Dmitry Gulevich, Leicestershire (GB)

Correspondence Address: HARRINGTON & SMITH, 4 RESEARCH DRIVE, Suite 202, SHELTON, CT, 06484-6212, US

(21) Appl. No.: 12/312,408

(22) PCT Filed: Nov. 8, 2007
(86) PCT No.: PCT/GB2007/004261

§ 371 Date: Dec. 14, 2009

(30) Foreign Application Priority Data
Nov. 8, 2006 (GB) 0622211.1

(51) Int. Cl. H03H 2/00

(52) U.S. Cl. 333/24 R; 327/367; 333/99 S

(57) ABSTRACT

A fluxonic device including a closed loop transmission line; an additional transmission line and a junction at which the closed loop transmission line and the additional transmission line meet. An apparatus including a fluxon container for containing one or more fluxons; a fluxon interface along which a fluxon can propagate; a junction where the fluxon container and fluxon interface meet; and a controller for controlling a fluxon at the junction. An electromagnetic radiation generator comprising: a fluxon transmission line having a length, a depth and a width and including a perturbation in the length-wise direction; a mechanism for applying a driving electric current in a depth-wise direction; and a magnetic field generator for generating a magnetic field in a width-wise direction.

Embodiments of the present invention relate to fluxonic devices. In particular, some embodiments, relate to fluxon generation or combination.

### BACKGROUND TO THE INVENTION

Fluxons are conventionally generated by applying a strong magnetic field to a Josephson transmission line. When a driving electric current is applied, a flow of fluxons is realized. However, such a system has significant drawbacks. It is very sensitive to electric current fluctuations and external noise. In addition, the strong magnetic fields used affect adjacent equipment.

### BRIEF DESCRIPTION OF THE INVENTION

According to one embodiment of the invention there is provided a fluxonic device comprising: a closed loop transmission line; an additional transmission line; and a junction at which the closed loop transmission line and the additional transmission line meet.

Such a device enables the generation and use of fluxons without the need for strong magnetic fields and with reduced sensitivity to noise.

According to another embodiment of the invention there is provided an apparatus comprising: a fluxon container for containing one or more fluxons; a fluxon interface along which a fluxon can propagate; a junction where the fluxon container and fluxon interface meet; and a controller for controlling a fluxon at the junction.

A fluxon container is a structure that is arranged to contain fluxons permanently or temporarily. An example of a fluxon container is a long Josephson junction formed as a closed loop.

A fluxon interface is an input interface for fluxons via which a fluxon is provided to the fluxon or an output interface for fluxons via which a fluxon is provided from the container. The fluxon interface typically comprises a transmission line for propagating fluxons.

The junction is where the fluxon container and fluxon interface meet. The angle at which the fluxon interface and fluxon container meet may affect the characteristics of the apparatus.

The controller may control the energy of a fluxon as it approaches the junction.

Such an apparatus enables the generation and use of flow of fluxons without the need for strong magnetic fields and with reduced sensitivity to noise.

### BRIEF DESCRIPTION OF THE DRAWINGS

For a better understanding of the present invention reference will now be made by way of example only to the accompanying drawings in which:

FIG. 1 schematically illustrates a cross-sectional side view of a long Josephson junction;

FIG. 2 schematically illustrates, in plan view, an example of how a closed loop (annular) JTL structure may be formed;

FIG. 3A illustrates a T-junction fluxonic device;

FIG. 3B illustrates the use of the T-junction fluxonic device for output fluxon generation;

FIG. 3C illustrates the I-V characteristic of the T-junction fluxonic device;

FIG. 3D schematically illustrates a multilayer T-junction fluxonic device;

FIG. 4A illustrates a σ-fluxonic device;

FIG. 4B illustrates the use of the σ-fluxonic device for output fluxon generation;

FIG. 4C illustrates the I-V characteristic of the σ-fluxonic device;

FIG. 4D schematically illustrates a multilayer σ-fluxonic device;

FIG. 5A schematically illustrates a fluxonic device that operates as an output fluxon generator;

FIG. 5B schematically illustrates a fluxonic device that operates as an input fluxon trap operable as a trap, an input fluxon generator or a polarization reverser;

FIG. 6 schematically illustrates an input fluxon generator;

FIG. 7A schematically illustrates a polarization reverser;

FIG. 7B schematically illustrates a breather generator;

FIG. 8 illustrates how the critical initial velocity for trapping of a fluxon-antifluxon pair is expected to depend on damping;

FIG. 9 illustrates a remote sensing device;

FIG. 10 schematically illustrates a fluxon interferometer;

FIG. 11 schematically illustrates a conceptual fluxon entangler;

FIGS. 12A and 12B schematically illustrate a fluxon transistor or switch.

FIG. 13 schematically illustrates, in perspective view, a fluxon transmission line comprising a perturbation region for causing electromagnetic radiation;

FIG. 14A illustrates a fluxon transmission line in which a discrete step-like change in the width W of the fluxon transmission line marks boundaries for the perturbation region;

FIG. 14B illustrates a fluxon transmission line in which a progressive change in the width W of the fluxon transmission line marks boundaries for the perturbation region; and

FIG. 15, illustrates a closed-loop fluxon transmission line with a perturbation region for causing electromagnetic radiation.

### DETAILED DESCRIPTION OF EMBODIMENTS OF THE INVENTION

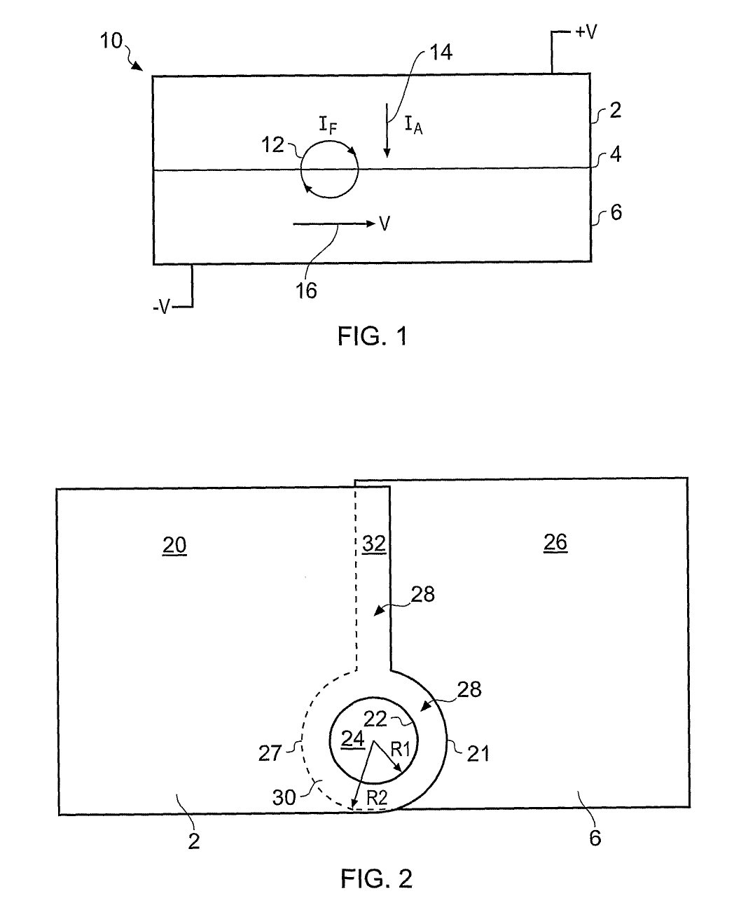

FIG. 1 schematically illustrates a cross-sectional side view of a long Josephson junction 10. The long Josephson junction 10 comprises a long and continuous first superconducting layer 2; a long and continuous second superconducting layer 6; and an insulating film 4 between the first and second superconducting layers 2, 6.

The first superconducting layer 2 has a width W (into the page) and extends in a first plane (perpendicular to the plane of the page). The second superconducting layer 6 has a width W (into the page) and extends in a second plane parallel to first plane. The insulating film 4 has a width W (into the page) and extends in a third plane parallel to and positioned between the first and third planes.

The superconducting layers 2, 6 may for example be formed from niobium or high temperature superconductors (HTSC). In the case of HTSC, the device can be implemented either as a stack containing multiple layers or a single layer.

The insulating film 4 is typically oxide in case of fabricated Josephson junctions or is naturally formed between intrinsic layers of high temperature superconductors (HTSC). Typically a few nm thick.

A fluxon 12 propagates freely parallel to the third plane. It is positioned across the contact interfaces between the first superconducting layer 2 and the insulating film 4 and between the second superconducting layer 6 and the insulating film 4. A fluxon 12 is a Josephson vortex. It is a self-generating circulating superconducting current I_{F} with an associated magnetic flux quantum. A fluxon 12 corresponds to a 2π kink of the quantum phase difference between the two superconducting layers 2,6.

If a net electrical current I_{A} 14 is applied across the long Josephson junction 10, it causes the fluxon 12 to move with a net velocity 16. The greater the net applied electric current I_{A} the greater the net velocity of the fluxon (until a relativistic limit).

The long Josephson junction is therefore able to operate as a Josephson transmission line (JTL) along which a fluxon 12 can propagate.

The energy of a fluxon within a JTL increases with fluxon velocity (increases with increasing applied electric current) and the relativistic mass of the fluxon (increases with increasing width W of the JTL).

FIG. 2 schematically illustrates, in plan view, an example of how a closed loop (annular) continuous JTL structure 30 may be formed. A closed loop JTL structure 30 is a long Josephson junction 10 that curves in the plane of the junction (parallel to the plane of the paper) so that is returns on itself forming a loop. The loop may, but need not be, substantially circular or elliptical in shape.

A first sheet 20 of superconducting material overlies at least a portion of a second sheet 26 of superconducting material and is separated therefrom by a thin insulating film 4 (not illustrated in FIG. 2). The region of overlap 28 forms a closed loop JTL structure 30.

The first sheet 20 of superconducting material forms the first superconducting layer 2 of the closed loop JTL structure 30. The first sheet 20 has a curved extremity 21 that is used to define an outer edge of the closed loop JTL structure 30. The first sheet 20 comprises a hole 24. The hole 24 has a curved inner edge 22 that is used to define an inner edge of the closed loop JTL structure 30.

The second sheet 26 of superconducting material forms the second superconducting layer 6 of the closed loop JTL structure 30. The second sheet 26 has a curved extremity 27 that is used to define an outer edge of the closed loop JTL structure 30. The second sheet 26 comprises a hole 24. The hole 24 has a curved inner edge 22 that is used to define an inner edge of the closed loop JTL structure 30.

In the example illustrated, the overlap region is an annulus defined by an inner radius R1 and an outer radius R2. The outer radius is defined by the radius of curvature of the curved extremities 21, 27. The inner radius is defined by the shared hole 24 and the radius of curvature of the hole's inner edge 22.

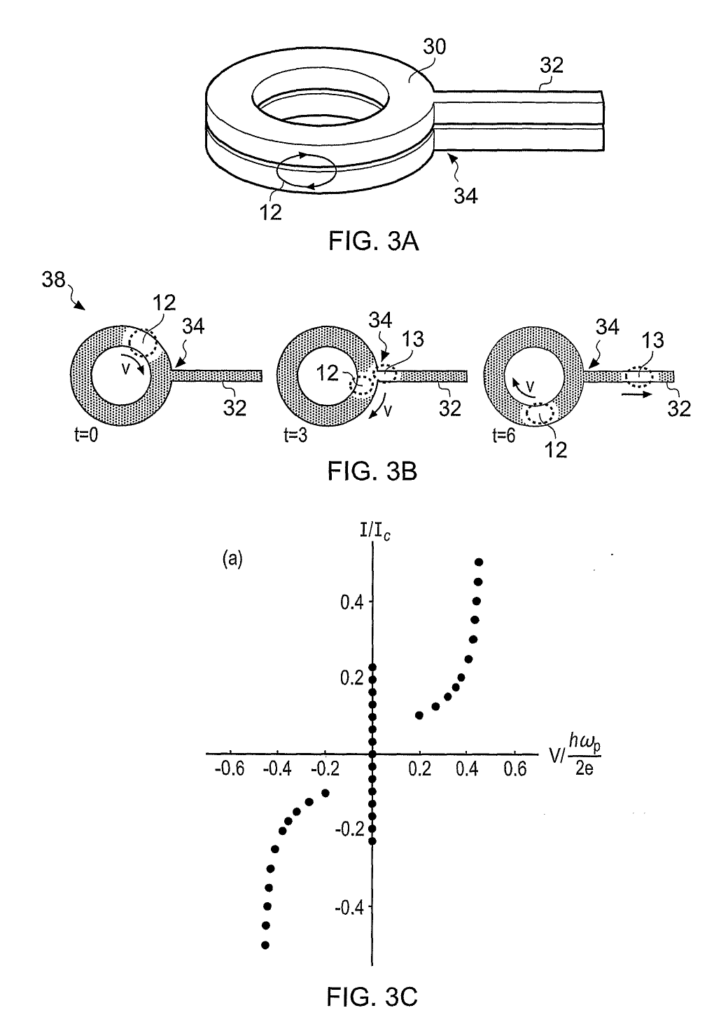

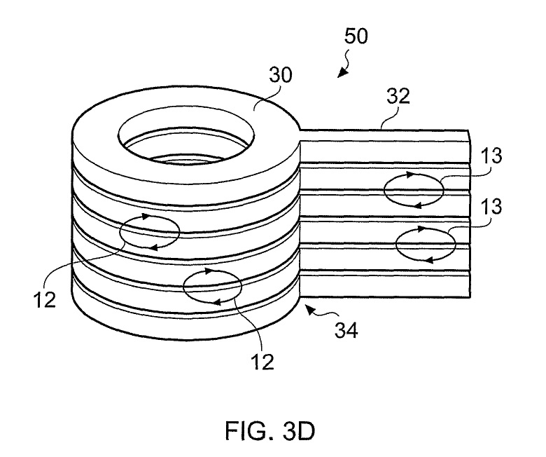

A closed loop continuous JTL structure 30 may be used in the fluxonic devices illustrated in FIGS. 3, 4, 5, 6, 7, 9, 10, 11 and 12 as a fluxon container or trap. An analogy is drawn between electronic devices that generate and/or use a flow of electrons and fluxonic devices that generate and/or use a flow of fluxons.

The closed loop structure is continuous in that as one traverses the loop one travels along the Josephson junction and not through multiple Josephson junctions.

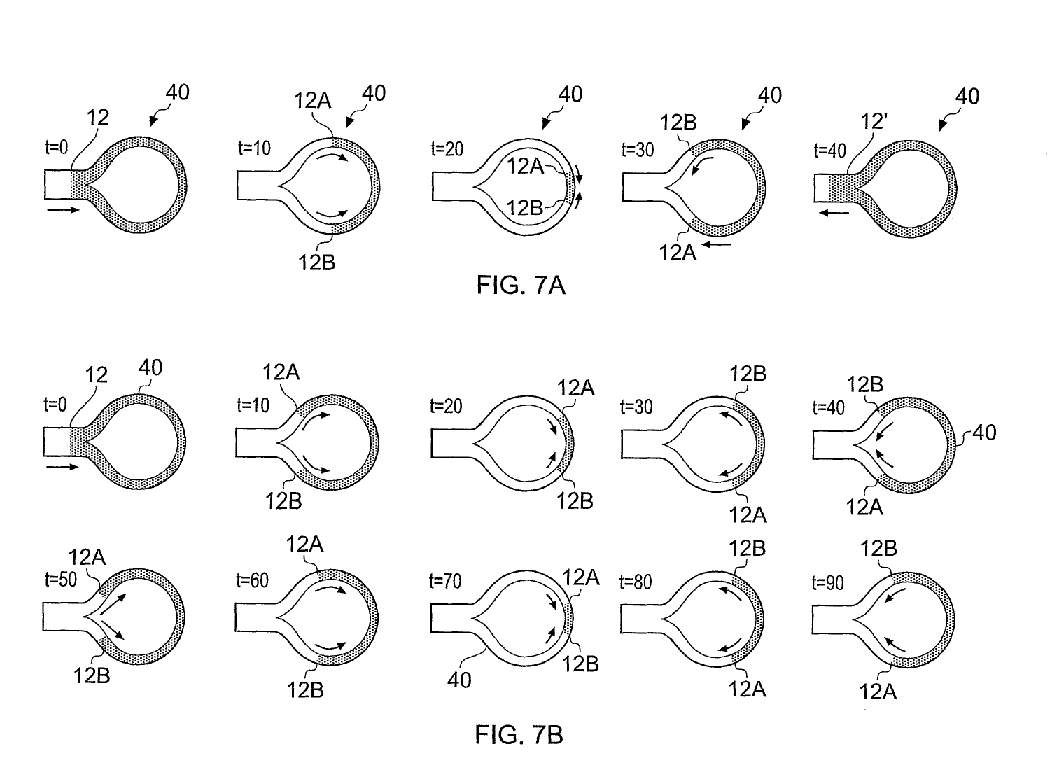

FIGS. 3A, 3B, 3D, 4A, 4B, 4D, 6, 7A, 7B, 10, 11, 12A and 12B schematically illustrate fluxonic devices that have closed loop JTL structures 30 used in fluxon generation. The fluxons may be generated within the closed loop JTL structure, if the ‘parent’ fluxon is input along the additional JTL 32 to the closed loop JTL structure 30 (see FIGS. 7A, 7B, 10, 11, 12A, 12B for examples of input fluxon generators). The generated fluxon may be output along the additional JTL 32, if the ‘parent’ fluxon is trapped within the closed loop JTL structure 30 (see FIGS. 3B, 4B, 5A, 7A for examples of output fluxon generators).

The fluxonic devices comprise a closed loop JTL structure 30 which operates as a fluxon container/trap containing at least one fluxon 12. An additional JTL 32, meets, at junction region 34, with the closed loop JTL structure 30 in the same planes as the closed loop JTL structure 30. The respective first superconducting layer 2, insulating film 4 and second superconducting layer 6 of the closed loop JTL structure 30 and the additional JTL 32 are aligned.

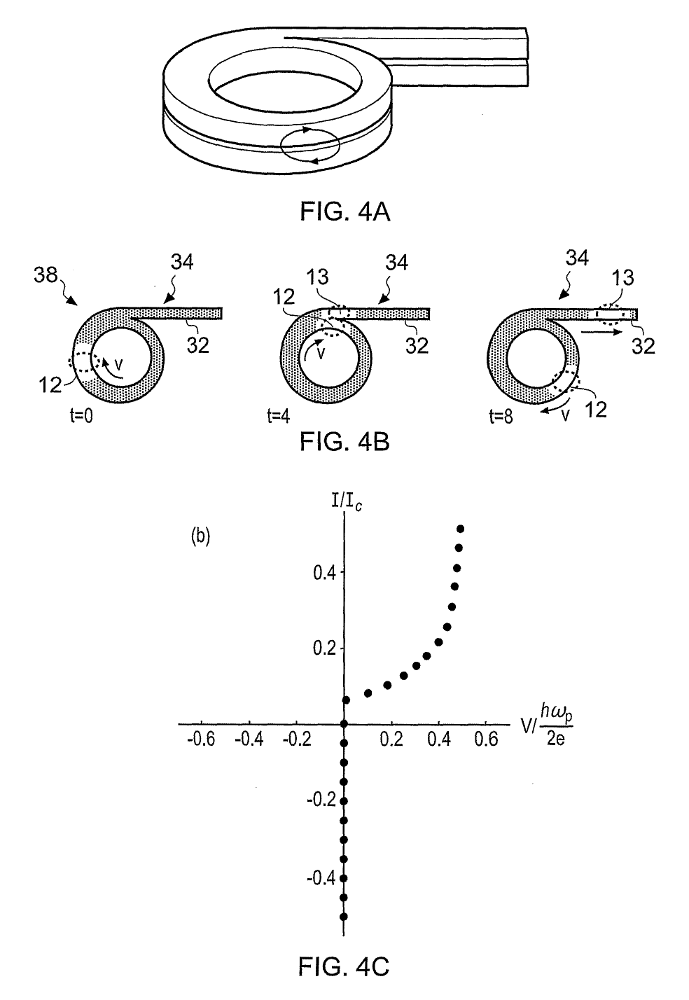

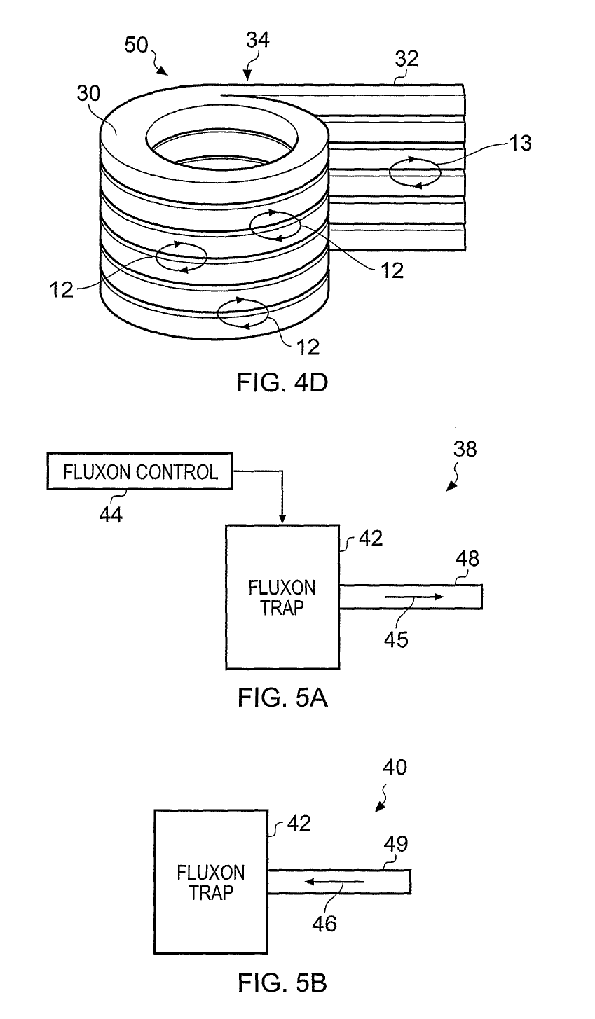

FIG. 3A illustrates a T-junction fluxonic device which may be used as an input fluxon generator or an output fluxon generator. FIG. 4A illustrates a σ-fluxonic device which may be used as an output fluxon generator.

The additional JTL 32 operates in an output fluxon generator implementation as a fluxon output that propagates fluxons from the closed loop JTL structure 30.

The additional JTL 32 operates in a fluxon input generator implementation as a fluxon input providing fluxons to the closed loop JTL structure 30 for containment.

The angle of attack of the additional JTL 32 to the closed loop JTL structure 30 at junction 34 may be varied. In FIG. 3A, it is perpendicular forming a T-shaped junction 34. In FIG. 4A, it is tangential forming a Y-shaped junction 34.

### Fluxon Generation

The controlled creation of fluxons at the junction of two straight JTLs is described in ‘Flux Cloning in Josephson Transmission Lines’, Phys Rev Lett, 017004-1 to 4, Gulevich and Kusmartsev.

The process of creating a new ‘baby’ fluxon 13 at a junction 34 depends upon the kinetic energy of the original ‘mother’ fluxon 12. If a fluxon 12 is moving very slowly, it does not have enough kinetic energy to give birth to a new fluxon 13. Then the junction 34 acts as a barrier and the fluxon 12 is just reflected from it. However, if the fluxon 12 has enough energy to overcome the barrier, that fluxon 12 acts as a mother and a new fluxon 13 is born in the additional JTL.

### Output Fluxon Generation

FIG. 5A schematically illustrates a fluxonic device that operates as an output fluxon generator 38. A fluxon container 42 traps a fluxon. A fluxon controller 44 controls the flow of fluxons (fluxon current) 45 produced by the fluxon container in the output 48.

The container/trap 42 will typically be a closed loop JTL structure 30. The output 48 is typically an additional JTL 32 joined to the closed loop JTL structure 30 at a junction 34. The fluxon controller 44 controls the electric current passing across the long Josephson junction of the closed loop JTL structure 30.

The use of a closed loop JTL structure 30 as a container for a fluxon, enables a driving electric current 14 to be applied increasing the velocity of the fluxon and its kinetic energy. When the energy of the fluxon exceeds a threshold output fluxon generation occurs at the junction 34 (see FIGS. 3B and 4B).

The generated fluxon 13 moves along the additional JTL 32, while the “mother” fluxon 12 continues its rotation in the closed loop JTL structure 30. Then the cycle repeats.

Thus a train of baby fluxons 13 can be created—a flow of fluxons (fluxon current) 45. The number of fluxons created per second depends upon the speed of the trapped fluxon, which depends upon the applied electrical driving current and the width of the JTL forming the closed loop JTL structure 30.

No external magnetic field is needed to generate a flow of fluxons (fluxon current).

### T-Junction Output Fluxon Generator

There is an energy barrier associated with the T junction 34 (FIG. 3B). There is some threshold value of the driving current required to activate the fluxon generation process. The critical current may be given by the formula (I) which relates the critical driving current with geometrical parameters of the T junction,

$${γ}_{c}^{T} = \frac{4 W}{π ( 2 {W}_{0} + W )} \qquad ( 1 )$$

where γ=j/j_{c}, j is a density of the driving current and j_{c} is the critical current density, W₀ is the width of the closed loop JTL structure 30 and W is the width of the additional JTL 32.

The T-junction fluxon generator may generate either fluxons or antifluxons depending on the direction of the applied current. This symmetry is reflected in its I-V characteristic (FIG. 3C). The I-V characteristic shows hysteretic behavior due to the energy barrier associated with the T junction.

### σ Output Fluxon Generator

A σ-fluxonic device (FIG. 4) has an advantage that there is no barrier associated with the junction 34. Instead, a Y junction 34 is used that connects smoothly the additional JTL 32 with the closed loop JTL structure 30. There is no nucleation barrier in this case. Instead, the nucleation energy is accumulated by the trapped fluxon 12 during its rotation in a potential associated with an increasing width W of the closed loop JTL structure 30. The absence of an abrupt barrier means that there are no parasitic plasma modes and less energy losses.

Let the width of the closed loop TJL structure 30 grow linearly along its circumference,

$$W ( x ) = Δ R + \frac{x}{2 π R} W$$

with R=Rᵢ+ΔR and fixed internal radius of the ring Rᵢ. x is a coordinate along circumference of the ring. In 1D approximation the potential energy of the trapped fluxon is given by the integral

$$V = {\int }_{0}^{L} d xW ( x ) [ \frac{{ϕ}_{x}^{2}}{2} + 1 - cos ϕ + γ ( x ) ϕ ] \qquad ( 2 )$$

where L=2πR. Here and further we work with normalized units with coordinates and distances normalized to the Josephson penetration length λ, velocity normalized to the Swihart velocity c time scaled by ωₚ⁻¹ where ωₚ is the plasma frequency, the energy normalized to

j_{c}λⱼ²Φ₀/2π

where

Φ₀=h/2e

standing for the unitary flux quantum and j_{c} for the critical current density.

In case of boundary conditions

$$\{ \begin{matrix}n \cdot ∇ ϕ {\vert}_{\partial {Ω}_{i}} = 0 & on internal boundary \partial {Ω}_{i} \\ n \cdot ∇ ϕ {\vert}_{\partial {Ω}_{e}} = γ ( Δ R + W / 2 ) & on external boundary \partial {Ω}_{e}\end{matrix} \qquad ( 4 )$$

with constant magnetic field component induced by the driving current and parallel to the boundary of the Josephson junction. Assuming the width W(x) is a slowly varying function of x and substituting soliton solution

φ(x,t)=4 arctan exp(x−x₀)

describing a resting fluxon to (9) we obtain the effective potential energy

V(x₀)=8W(x₀)−γ(ΔR+W/2)2πx₀

Thus, the threshold value of the driving current required to activate the fluxon generation process is:

$${γ}_{c}^{σ} = \frac{2 W}{{π}^{2} R ( Δ R + W / 2 )}$$

The σ-fluxonic device can only generate output fluxons. The asymmetry of the σ is reflected in its I-V characteristic (FIG. 4C). The σ-fluxonic device may operate as a ratchet, diode or rectifier.

FIG. 3D schematically illustrates a multilayer T-junction fluxonic device 50. FIG. 4D schematically illustrates a multilayer a fluxonic device 50. These structures can be realized by layered superconductors such as BSCCO.

### Fluxon Trap

FIG. 5B schematically illustrates a fluxonic device that operates as a input fluxon trap 40. A fluxon container 42 is used to trap fluxons. An input 49 provides fluxons as a flow of fluxons (fluxon current) 46 to the fluxon container 42. A fluxon controller 44 controls the flow of fluxons (fluxon current) 46.

The fluxon container will typically be a closed loop JTL structure 30. The input 49 is typically an additional JTL 32 joined to the closed loop JTL structure 30. The fluxon controller may for example control the flow of fluxons (fluxon current) 46 along the additional JTL by controlling the net electrical current 14 applied across the additional JTL 32. Controlling this net electrical current controls the speed of the fluxons.

### Input Fluxon Generator

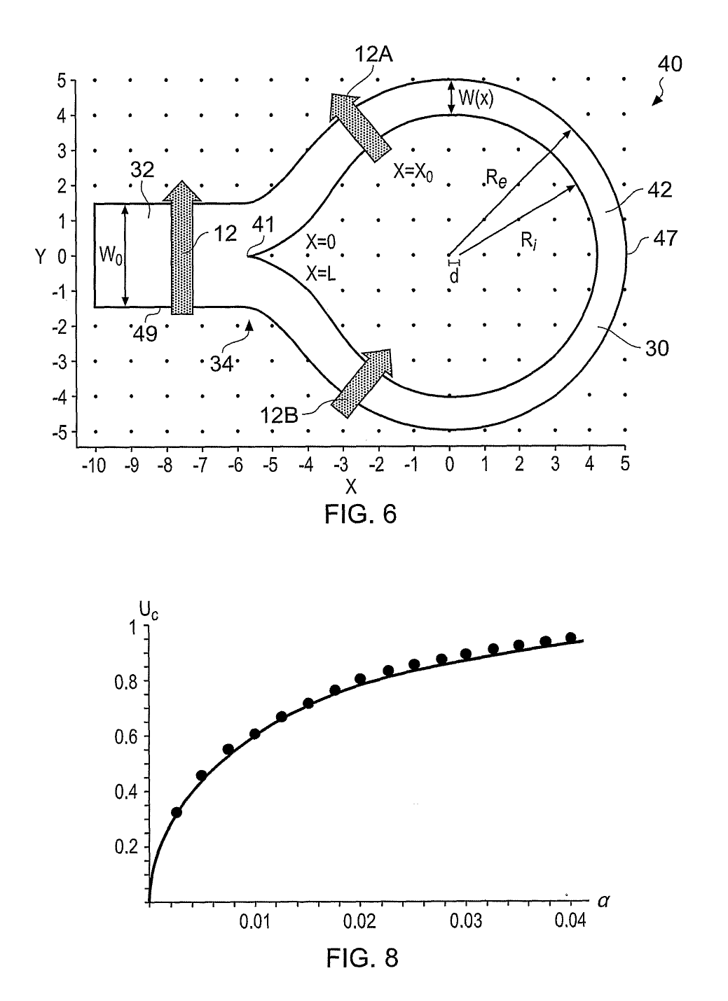

The input fluxon trap may be operated as a input fluxon generator 40 as illustrated in FIGS. 6 and 7B

A flow of fluxons (fluxon current) 46 is created by a current pulse at the end of the additional JTL 32 and then moves towards the junction 34 with closed loop JTL structure 30.

A fluxon 12 in the flow of fluxons (fluxon current) 46 propagates in the additional JTL 49 towards the junction 34. For velocities of the incident fluxon greater than a threshold T, the fluxon 12 passes through the junction 34 without reflection and splits into two solutions—a fluxon and an antifluxon which have opposite polarity. The junction 34 has a Y shape with a sharp edge 41 directed towards an arriving fluxon 12. This sharp edge reduces the energy threshold required for fluxon and antifluxon pair creation.

A dashed arrow in FIG. 6 represents a parental fluxon 12 approaching the T-junction 34. The plain arrows represent the fluxon-antifluxon pair 12A, 12B induced by the split parental fluxon 12.

In order to trap the pair of fluxon/antifluxon in the closed loop JTL structure 30 some minimal damping is needed. In this case (illustrated in FIG. 7B), after being injected into the closed loop JTL structure 30, the fluxon-antifluxon pair 12A, 12B hasn't enough energy to leave the closed loop JTL structure 30. The confined fluxon and antifluxon experience multiple collisions and eventually form a bound state in the form of an oscillating breather.

In order to create a trapping potential for a fluxon-antifluxon pair and a breather, the closed loop JTL structure 30 may be made thinner on the side 47 opposite to the junction 34. The fluxon and antifluxon move in opposite directions on the closed loop JTL structure 30 and collide at the narrowest point 47 of the closed loop JTL structure 30. At the point 47 the fluxon and the antifluxon 12A, 12B have the maximal kinetic energy as well as the strongest dissipation of energy.

In FIG. 6, the closed loop JTL structure 30 is constrained by two circles of radii Rₑ and Rᵢ with centers shifted by distance d with respect to each other. The width of the AJJ depends on the coordinate x along the ring and is given by

W(x)≅ΔR+d cos(x/R),

where ΔR=Rₑ−Rᵢ is the average width, R=(Rₑ+Rᵢ)/2 is the average radius and 0<x<L.

It can be shown that the theoretical critical initial fluxon velocity, below which the incident fluxon should be traveling, for breather formation is:

$${u}_{c} = \sqrt{1 - {( \frac{8 {W}_{0}}{{E}_{0}} )}^{2}}$$

where W₀ is width of the additional JTL

E₀=8W₀/\sqrt{1−u₀²}

The fluxon controller 44 may be used to make sure the incident fluxon propagating along the additional JTL 32 is below this critical velocity.

FIG. 8 illustrates how the critical initial velocity for trapping of a fluxon-antifluxon pair is expected to depend on damping.

### Polarity Reverser

The fluxonic devices illustrated in FIGS. 3A and 6 may be used to reverse the polarity of a fluxon.

In a case of zero or low damping (illustrated in FIG. 7A) the fluxon and antifluxon 12A, 12B propagate in the closed loop JTL structure 30 in different directions, pass through each other and merge again at the junction 45. The combined “giant” antifluxon 12′ leaves the closed loop JTL structure 44 and starts to propagate along the additional JTL 32 in the direction opposite to the original fluxon 12.

### INDUSTRIAL APPLICABILITY

A closed loop JTL structure 30 may be used in the fluxonic devices illustrated in FIGS. 3, 4, 5, 6, 7, 9, 10, 11 and 12. The closed loop JTL structure may be used to generate fluxons at its junction with an additional JTL, it can be used to permanently trap fluxons and it can be used to temporarily trap fluxons in order to reverse a fluxon polarity. An analogy is drawn between electronic devices that generate and/or use a flow of electrons and fluxonic devices that generate and/or use a flow of fluxons.

### THz Generator

An output fluxon generator 38 may be used to generate THz radiation. In the examples of FIGS. 3B and 4B, when the fluxon 13 reaches the end of the additional JTL 32 it may induce THz radiation at the end of JTL propagating in the same direction as the fluxon.

A fluxon trap may be operated as an input fluxon generator to generate THz radiation. An oscillating breather may emit in the THz region.

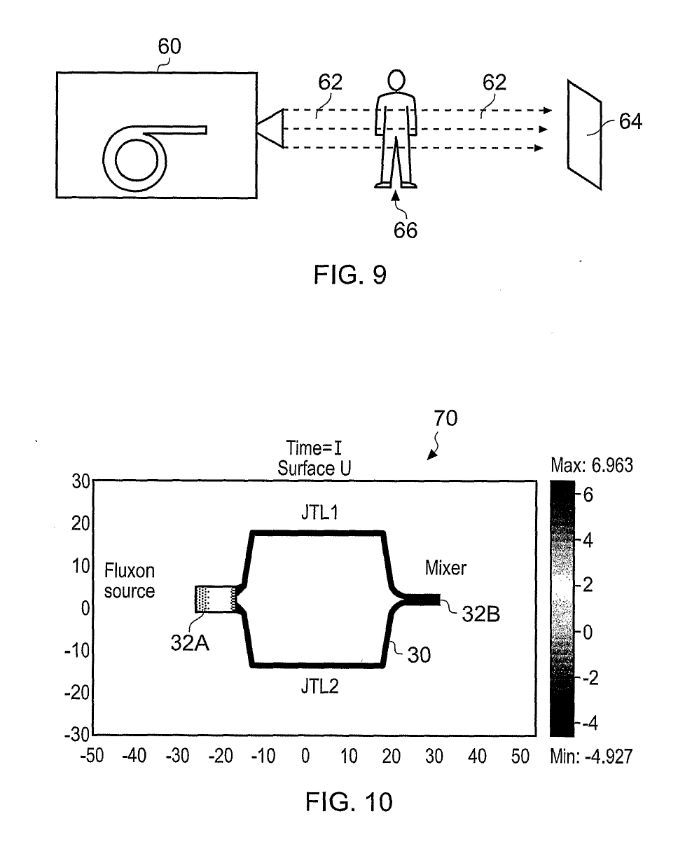

A fluxonic device that generates THz radiation may be incorporated into a remote sensing device 60, as illustrated in FIG. 9 that uses THz radiation 62 to take a transmission image 64 of an object 66. Such a remote sensing device 60 may be particularly useful for identifying or locating items carried by or located within person and for medical diagnosis.

### Magnetic Field Measurement

FIG. 10 schematically illustrates another fluxonic device 70—a fluxon interferometer. The fluxon interferometer 70 comprises a closed loop JTL structure 30 divided into an upper limb JTL1 and a lower limb JTL2. The closed loop JTL structure 30 is fed with fluxons via an input first additional JTL 32A. The closed loop JTL structure 30 provides fluxons as output via a second additional JTL 32B. The first additional JTL 32A and the second additional JTL 32B are at diametrically opposed sides of the closed loop structure 30.

A fluxon arriving via the input 32A is converted to a fluxon and antifluxon pair as described in relation to FIG. 6. The fluxon and antifluxon move along different limbs of the closed loop structure 30 and may therefore experience slightly different external magnetic fields. One fluxon will be delayed relative to the other. In this way it is possible to investigate the inhomogeneities associated with some external magnetic field via the process of the interference between these two fluxons.

A fluxon generator may also be used as a detector for a magnetic field. The fluxon generator may be operated on one side (just below/just above) its operational threshold. The application of a magnetic field alters the fluxon energy and changes the state of operation of the fluxonic device to the other side of the operational threshold (just above/just below). The fluxonic device therefore acts as a two-state bi-stable device that is switched by an applied magnetic field.

### Entanglement

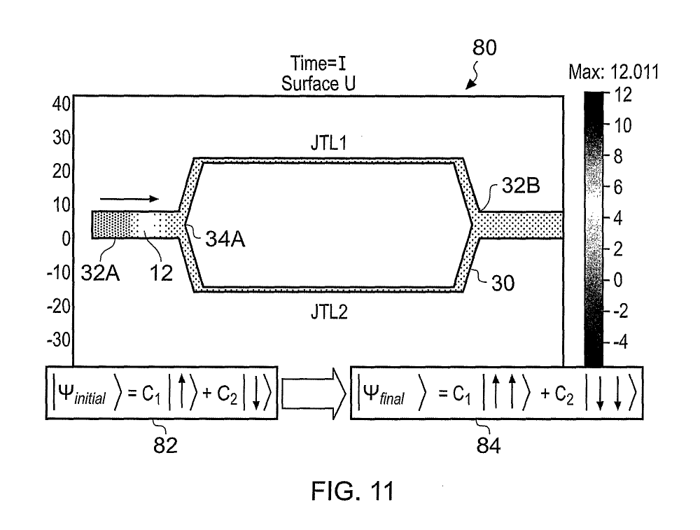

FIG. 11 schematically illustrates a conceptual fluxonic device 80—a fluxon entangler. A fluxon 12 is sent towards the Y junction 34A, it will split into two identical fluxons moving in different directions. Now suppose we have prepared a fluxon-antifluxon superposition state 82 and send it to the junction 34A. The superposition state 82 will transform into the entangled state 84 of two spatially separated fluxons.

The fluxon entangler 80 is very similar to the fluxon interferometer 70, but the operation and purpose of this device is different. It is designed for quantum fluxons. Therefore, the width of the input JTL 32A is much smaller than the Josephson penetration depth.

### Transistor/Switch

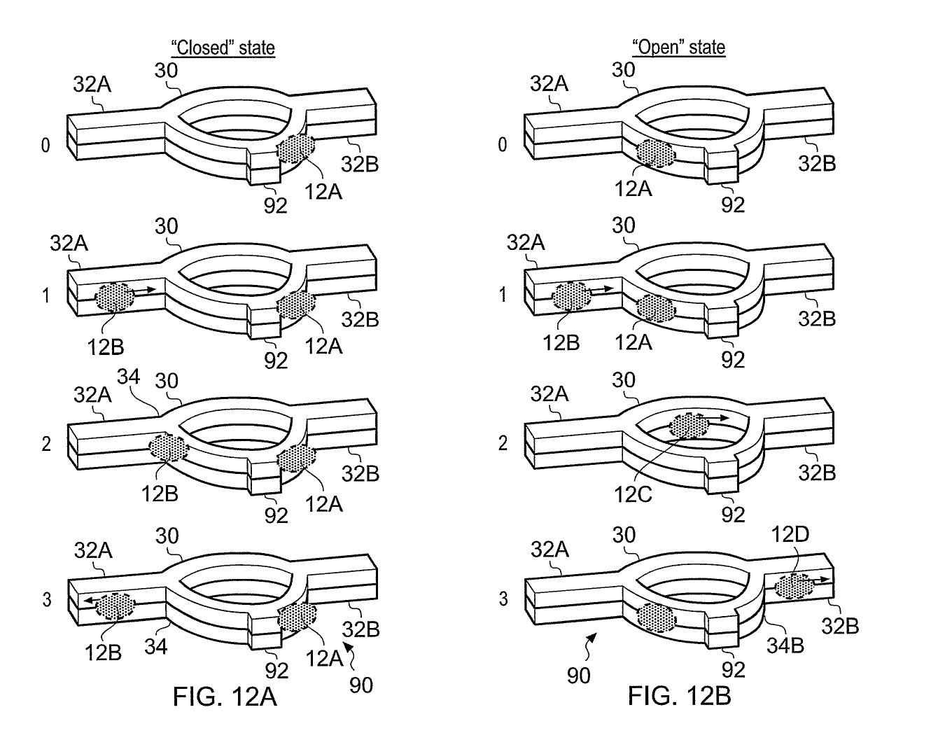

FIGS. 12A and 12B schematically illustrate a fluxonic device 90—a fluxon transistor or switch.

The fluxonic device 90 comprises a closed loop JTL structure 30. It also comprises a first additional JTL 32A and a second additional JTL 32B at opposing sides of the closed loop structure 30 which operate as a fluxon input and fluxon output. Between the first and second additional JTLs there is placed a microshort impurity 92.

A fluxon 12A is trapped within the closed loop structure 30. The position of the trapped fluxon within the closed loop structure 30 is controlled by an applied magnetic field.

FIG. 12A illustrates a first state. The trapped fluxon 12A is positioned between the microshort impurity and the fluxon output 32B. An input fluxon 12B does not have enough energy to enter the closed loop JTL structure 30 and is reflected by the junction 34A.

FIG. 12B illustrates a second state. The trapped fluxon 12A is positioned between the microshort impurity and the fluxon input 32A. An input fluxon 12B does not have enough energy to enter the closed loop JTL structure 30 by itself, but does in combination with the trapped fluxon 12B. The combination fluxon 12C traverses the closed loop structure to the junction 34B with the additional JTL 32B, where an out fluxon 12D is generated.

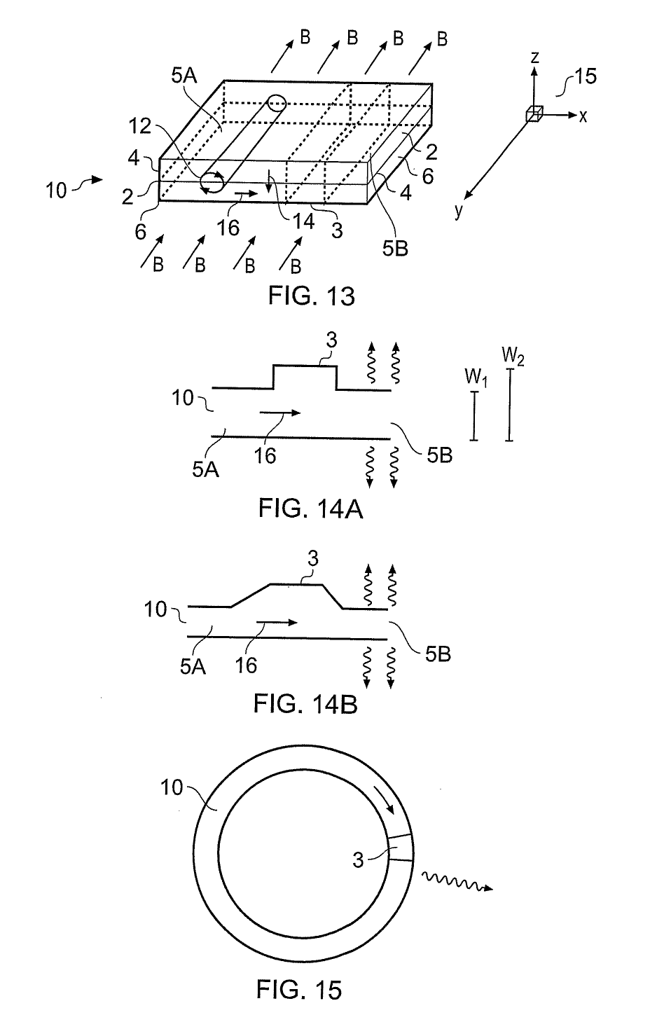

FIG. 13 schematically illustrates, in perspective view, a fluxon transmission line 10. The fluxon transmission line 10 is a long Josephson junction similar to that described with reference to FIG. 1. It however has a perturbation region 3.

The Fig includes a co-ordinate system 15 which defines three orthogonal vertices (x,y,z). The fluxon transmission line 10 has a length in the x-direction, a width in the y-direction and a depth in the z-direction.

A mechanism (not illustrated) applies a driving electric current 14 that causes the fluxon 12 to move with a net velocity 16 in the length-wise direction (+x).

The fluxon transmission line 10 illustrated in FIG. 13 differs from that illustrated in FIG. 1 in that the fluxon transmission line 10 has a perturbation region 3 and in that a magnetic field B is applied is a width-wise direction (y) by a magnetic field generator (not illustrated).

The perturbation region 3 is used to transform energy of a fluxon. As a fluxon moves from an upstream area 5A that is upstream of the perturbation region 3, a portion of its kinetic energy is converted into potential energy. Then as the fluxon moves from the perturbation region 3 to a downstream area 5B, some or all of the potential energy is converted into elastic energy. The perturbation causes the fluxon in the downstream area 5B to vibrate and radiate electromagnetic (EM) waves.

The applied magnetic field B may be used to maintain coherence in the EM radiation as it constrains the direction of vibration of the fluxons 12.

The perturbation region 3 is a region in which one or more characteristics of the fluxon transmission line 10 are different to the upstream and downstream regions 5A, 5B. As the perturbation region 3 is traversed by a fluxon 12 moving in the length-wise direction (+x) its kinetic energy is changed.

The perturbation region 3 may increase (compared to the upstream and downstream regions 5A,5B) a superconducting critical current for the fluxon transmission line 10.

The perturbation region 3 may have a different width W2 compared to the widths of the fluxon transmission line 10 in the upstream and downstream regions 5A, 5B.

FIG. 14A illustrates a fluxon transmission line 10 in which a discrete step-like change in the width W of the fluxon transmission line 10 marks boundaries for the perturbation region 3.

FIG. 14B illustrates a fluxon transmission line 10 in which a progressive change in the width W of the fluxon transmission line 10 marks boundaries for the perturbation region 3.

The perturbation region 3 may have a different composition compared to the upstream and downstream regions 5A, 5B of the fluxon transmission line 10. For example, the perturbation region 3 may be doped with one or more impurities, the region 3 may have a different type of thickness of insulating film 4 and/or first superconducting layer 2 and/or second superconducting layer 6.

The size of the perturbation region 3 in the length-wise direction may be shorter than a Josephson length.

The frequency of the EM radiation emitted by the downstream region 5B of the fluxon transmission line 10 may be controlled by the width of the downstream region 5B.

The intensity of the EM radiation emitted by the downstream region 5B of the fluxon transmission line 10 may be controlled by controlling the amplitude of the driving electric current.

FIG. 15, illustrates a closed-loop fluxon transmission line with a perturbation region 3 for causing electromagnetic radiation.

Fluxon transmission lines with perturbations, such as for example those described above, may be used in a remote sensing device such as that illustrated in FIG. 9. When the fluxon transmission line 10 with a perturbation (as illustrated in FIGS. 13 to 15) is used the EM radiation is emitted transversely compared to the velocity of the fluxons.

Although embodiments of the present invention have been described in the preceding paragraphs with reference to various examples, it should be appreciated that modifications to the examples given can be made without departing from the scope of the invention as claimed.

Whilst endeavoring in the foregoing specification to draw attention to those features of the invention believed to be of particular importance it should be understood that the Applicant claims protection in respect of any patentable feature or combination of features hereinbefore referred to and/or shown in the drawings whether or not particular emphasis has been placed thereon.

I/we claim:

1. A fluxonic device comprising
a closed loop transmission line;
an additional transmission line and
a junction at which the closed loop transmission line and the additional transmission line meet.

2. A fluxonic device as claimed in claim 1, having operational characteristics controlled by the angle at which the additional transmission line meets the closed loop transmission line

3. A fluxonic device as claimed in claim 1, having operational characteristics controlled by the width or width variation of the additional transmission line

4. A fluxonic device as claimed in claim 1, having operational characteristics controlled by the width or width variation of the closed loop transmission line

5. (canceled)

6. (canceled)

7. A fluxonic device as claimed in claim 1, wherein the closed loop transmission line and the additional transmission line are Josephson transmission lines having long Josephson junctions.

8. A fluxonic device as claimed in claim 1, configured for operation as an input fluxon generator, for generating fluxons within the closed loop transmission line.

9. (canceled)

10. (canceled)

11. A fluxonic device as claimed in claim 1, wherein the width of the closed loop transmission line is arranged for breather formation.

12. A fluxonic device as claimed in claim 1, configured for operation as a reverse polarizer, for reversing the polarization of fluxons input to the closed loop transmission line.

13. A fluxonic device as claimed in claim 1, configured for operation as an output fluxon generator.

14. (canceled)

15. (canceled)

16. (canceled)

17. (canceled)

18. A fluxonic device as claimed in claim 1 operable as a device selected from the group comprising:
a switch, a magnetic field sensor, a radiation generator.

19. (canceled)

20. (canceled)

21. An apparatus comprising:
a fluxon container for containing one or more fluxons;
a fluxon interface along which a fluxon can propagate;
a junction where the fluxon container and fluxon interface meet; and
a controller for controlling a fluxon at the junction.

22. An apparatus as claimed in claim 21, wherein the controller controls an energy level of the fluxon at the junction.

23. An apparatus as claimed in claim 21, wherein the fluxon interface provides a fluxon to the fluxon container and wherein the controller controls an energy level of a fluxon that travel along the fluxon interface towards the fluxon container.

24. (canceled)

25. (canceled)

26. An apparatus as claimed in claim 21, wherein the fluxon interface receives a fluxon from the fluxon container and wherein the controller controls an energy level of a fluxon contained by the container.

27. (canceled)

28. (canceled)

29. An apparatus as claimed in claim 21, wherein the fluxon container is a closed loop Josephson Transmission Line structure having a varying width.

30. (canceled)

31. An apparatus as claimed in any one of claims 21 to 30, wherein the fluxon interface is an additional JTL having a varying width.

32. (canceled)

33. (canceled)

34. An electromagnetic radiation generator comprising:
a fluxon transmission line having a length, a depth and a width and comprising a perturbation in the length-wise direction;
a mechanism for applying a driving electric current in a depth-wise direction; and
a magnetic field generator for generating a magnetic field in a width-wise direction.

35. A generator as claimed in claim 34, wherein the fluxon transmission line is a Josephson transmission line having a long Josephson junction.

36. (canceled)

37. (canceled)

38. (canceled)

39. (canceled)

40. (canceled)

41. (canceled)

42. A generator as claimed in claim 34, wherein mechanism for applying a driving electric current is configured for user variation of the amplitude of the driving electric current.

43. A fluxonic device comprising:
a Josephson transmission line having a length, a depth and a width and comprising a perturbation in the length-wise direction;
a mechanism for applying a driving electric current in a depth-wise direction; and
a magnetic field generator for generating a magnetic field in a width-wise direction.

44. A method of generating electromagnetic radiation comprising:
driving a fluxon along a transmission line using an electric current; and
converting energy of the fluxon as it is driven along the transmission line into elastic energy for dissipation as electromagnetic energy.

45. (canceled)

46. A fluxonic device as claimed in claim 1, wherein the closed loop transmission line comprises a perturbation for causing electromagnetic radiation.

47. A fluxonic device as claimed in claim 1, wherein the additional transmission line comprises a perturbation for causing electromagnetic radiation.
